(19) United States
(12) Patent Application Publication
(10) Pub. No.: US 2026/0147044 A1
(43) Pub. Date: May 28, 2026

(54) Method and System for Early Detection of Abnormalities in Motor Ball Bearings

(71) Applicant: RICHTEK TECHNOLOGY CORP., Hsinchu County (TW)

(72) Inventors: Ta-Yung Yang, Taoyuan City (TW); I-Chi Lin, New Taipei City (TW); Tao-Yen Wei, Taoyuan City (TW); Ming-Cheng Chen, Taipei City (TW)

(21) Appl. No.: 19/048,866

(22) Filed: Feb. 8, 2025

Related U.S. Application Data
(60) Provisional application No. 63/723,595, filed on Nov. 22, 2024.

(51) Int. Cl. G01R 31/34; G01R 19/165; H02P 21/10; H02P 21/18; H02P 21/22

(52) U.S. Cl. CPC G01R 31/343; G01R 19/16533; H02P 21/10; H02P 21/18; H02P 21/22; H02P 2205/01; H02P 2207/05

(57) ABSTRACT

A method for detecting abnormalities of a motor includes generating, by a microcontroller, a quadrature current, calculating, using a low-pass filter, an average current based on the quadrature current, generating, by the microcontroller, a ripple current, comparing the ripple current with the average current, determining whether the ripple current deviates from the average current by more than a predetermined threshold for a specified duration, and triggering an alert signal when the ripple current deviates from the average current by more than the predetermined threshold for the specified duration.

### CROSS REFERENCE TO RELATED APPLICATIONS

This application claims the benefit of U.S. Provisional Application No. 63/723,595, filed on Nov. 22, 2024. The content of the application is incorporated herein by reference.

### BACKGROUND OF THE INVENTION

### 1. Field of the Invention

The present invention is related to feedback control, and more particularly to early detection of abnormalities in motor ball bearings.

### 2. Description of the Prior Art

Cooling fans are often used to cool electronic devices and thereby prevent such devices from overheating. For example, in data centers, fans play a critical role in ensuring that servers would not be damaged by excessive heat. Such cooling fans may include fans that are installed within tower servers and rack servers and used to cool internal components thereof, chassis-mounted fans used to cool blade servers and other electronic components housed within a chassis, rack-mounted fans used to cool servers and other electronic components housed within a rack, and large fans used as part of data center air conditioning and air handling systems. These cooling fans are important in upholding the optimal operation of computer systems. If, for some reason, the cooling fans fail to adequately dissipate excess heat, they can result in irreversible heat damage to the electronics.

The prior art patents (e.g., U.S. Pat. Nos. 6,400,113, 7,387,499, and 10,519,960) have disclosed techniques for monitoring, testing, and grouping fans with analogous characteristics to identify the cooling fans that operate beyond reference benchmarks (e.g., revolutions per minute (RPM)).

U.S. Pat. No. 6,400,113, “APPARATUS AND METHOD FOR MONITORING FAN SPEEDS WITHIN A COMPUTING SYSTEM,” describes an apparatus for monitoring fan speeds within a computing system including a tachometer turning with the fan, providing a tachometer signal including a number of pulses during each revolution of the fan. This tachometer signal is provided as an input to a signal generator in the form of a flip-flop, which generates a square-wave signal having transitions between high and low levels corresponding to tachometer signal pulses. The square-wave signals are provided as inputs to separate input ports of a microprocessor. These input ports are sequentially sampled at a rate providing at least two samples per period of the fastest square-wave signal, so that transitions of each square wave signal during a predetermined time interval can be detected and counted. For each input port, the number of counted transitions is compared to a stored acceptable value to establish whether the fan is operating in an acceptable speed range.

U.S. Pat. No. 7,387,499, “SYSTEM AND METHOD FOR TESTING THE OPERATION OF A COOLING FAN,” is directed to a method for testing the operation of a cooling apparatus of an information handling system. The method may include determining a first rotational speed for operating a fan of the cooling apparatus, with the first rotational speed being less than a maximum rotational speed of the fan. The method includes signaling the fan to rotate at the first rotational speed, and detecting a current rotational speed of the fan. The method includes comparing the detected current rotational speed of the fan to the first rotational speed of the fan, and if the detected current rotational speed is substantially equal to or greater than the first rotational speed of the fan, continuing an initialization process of the information handling system; and if the detected current rotational speed of the fan is less than the first rotational speed, causing further testing of the fan.

U.S. Pat. No. 10,519,960, “FAN FAILURE DETECTION AND REPORTING,” is related to fan failure detection and reporting system that organizes fans having similar characteristics into groups. The system establishes, for a given fan group, one or more reference characteristics and identifies, for each reference characteristic, a measure of tolerance. The system identifies as a problem fan a fan having a performance characteristic, obtained via monitoring, which exceeds a corresponding reference characteristic for the group to which the fan belongs by the measure of tolerance for the corresponding reference characteristic, and generates a notification that at least identifies the problem fan. In embodiments, the system is capable of determining the fan characteristics that are used for grouping and for identifying problem fans by monitoring the fans during operation thereof. Consequently, the system is capable of detecting problem fans even when the system initially has limited or no knowledge concerning the fans.

Regrettably, above mentioned prior art is insufficient in detecting fans operating at prescribed speeds but exhibiting indication of early-stage fan failures. Addressing this gap, the present innovation introduces a method and apparatus for accurate prediction of early-stage fan failures.

### SUMMARY OF THE INVENTION

An embodiment provides a method for detecting abnormalities of a motor. The method comprises generating, by a microcontroller, a quadrature current, calculating, using a low-pass filter, an average current based on the quadrature current, generating, by the microcontroller, a ripple current, comparing the ripple current with the average current, determining whether the ripple current deviates from the average current by more than a predetermined threshold for a specified duration, and triggering an alert signal when the ripple current deviates from the average current by more than the predetermined threshold for the specified duration.

Another embodiment provides a motor control system. The motor control system comprise an inverter, a motor coupled to the inverter, a Clarke Transform block coupled to the inverter, a Park Transform block coupled to the Clarke Transform block, a position and speed estimator coupled to the Park Transform block, a low-pass filter coupled to the position and speed estimator, a first subtractor coupled to the position and speed estimator, a first Proportional Integral (PI) controller coupled to the first subtractor, a second subtractor coupled to the first PI controller and the Park Transform block, and a space vector pulse width modulation (SVPWM) block coupled to the second PI controller, the position and speed estimator, and the inverter. The inverter is used to generate a first phase current, a second phase current, and a third phase current according to an input voltage and control signals. The motor is used to drive a cooling fan according to the first phase current, the second phase current, and the third phase current. The Clarke Transform block is used to generate a first stator current and a second stator current according to the first phase current and the second phase current through Clarke transformation. The Park Transform block is used to generate a direct current and a quadrature current according to a rotor angle, the first stator current and the second stator current through Park transformation. The position and speed estimator is used to generate a speed signal and the rotor angle according to the direct current and the quadrature current. The low-pass filter is used to generate an average current of the motor according to the quadrature current. The first subtractor is used to generate a first difference signal according to a control speed and the speed signal. The first Proportional Integral (PI) controller is used to generate a PI signal according to the first difference signal. The second subtractor is used to generate a second difference signal according to the PI signal and the quadrature current. The second Proportional Integral (PI) controller is used to generate a duty signal according to the second difference signal. The space vector pulse width modulation (SVPWM) block is used to generate the control signals for the inverter according to the duty signal and the rotor angle. The low-pass filter generates a ripple current according to the average current and the quadrature current and an alert signal is generated when the ripple current exceeds a predetermined deviation threshold.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A, FIG. 1B and FIG. 1C illustrate a motor control system according to an embodiment of the present invention.

FIG. 2 illustrates a flow diagram presenting a method for predicting failure of a cooling fan implemented by the motor control system of FIGS. 1A-1C.

FIG. 3 illustrates an exemplary quadrature current generated by the microcontroller during the operation of motor of FIGS. 1A-1C.

FIG. 4 illustrates an exemplary average current generated from the quadrature current by the low-pass filter of FIGS. 1A-1C.

FIG. 5 illustrates the resultant signal obtained from the subtraction operation between the quadrature current and the average current according to an embodiment.

FIG. 6 illustrates the ripple current obtained through filtering of the differential signal from the previous operation according to an embodiment of the present invention.

### DETAILED DESCRIPTION

The present disclosure provides a detailed description of various embodiments. While specific implementation details are presented herein to facilitate a comprehensive understanding of the disclosure, it will be apparent to those skilled in the art that the present invention may be realized without necessarily adhering to all such particularities. In certain instances, well-established methods, procedures, components, and circuits have been omitted from exhaustive description to avoid obscuring the present disclosure. It should be understood that technical features individually described in relation to a single drawing may be implemented either discretely or in combination with other features, as set forth in the present specification.

Fans are often used to cool electronic devices and thereby prevent such devices from overheating. For example, in data centers, fans play a critical role in ensuring that servers do not overheat. Such fans may include but are not limited to fans installed within tower and rack servers and used to cool internal components thereof, chassis-mounted fans used to cool blade servers and other electronic components housed within a chassis, rack-mounted fans used to cool servers and other electronic components housed within a rack, and large fans used as part of data center air conditioning and air handling systems.

In many data centers, the fans that are used to cool servers can be removed and replaced by other fans having different characteristics. For example, a chassis-mounted fan that can run at a maximum speed of 6000 RPM may be removed and replaced by a fan that can run at a maximum speed of 8000 RPM. This ability to swap out fans enables one who manages the data center to selectively install various types of fans (e.g., fans made by different manufacturers, different models of fans made by the same manufacturer, and fans having different characteristics) depending on a variety of factors such as cost and performance. For example, one may opt to install fans that provide the highest possible performance regardless of the cost. Another may opt to install fans that provide only the level of performance necessary for adequate server cooling under cost-down strategies.

It is desirable to monitor the performance of one or more installed fans to detect fans failures, as well as fans that are operating in a manner that is abnormal, sub-optimal, unsatisfactory, or indicative of a potential fan failure. This is especially true where the fans themselves do not have a built-in diagnostic control unit. In an environment described above, in which a variety of different fan types can be installed within a server, chassis, rack, or data center, it is possible that the expected characteristics of an installed fan or group of fans will be unknown to the monitoring entity. In such a case, it becomes difficult to determine whether a fan is operating as expected, since there is no data concerning expected characteristics against which to compare the monitored performance of the fan.

Described herein is a motor control system and method for the failure prediction of cooling fans, which addresses the issues with conventional fan-based cooling systems described above. The system may be used to organize fans having similar characteristics into groups. The system may further be used to establish one or more reference characteristic (e.g., input power and average current of the motor) for at least one cooling fan, and to identify a measure of tolerance or threshold for each reference characteristic. The system may further be used to identify a problem fan that operates and exceeds the measure of tolerance or threshold for the corresponding reference characteristic, and to generate an alarm signal that identifies the problem fan.

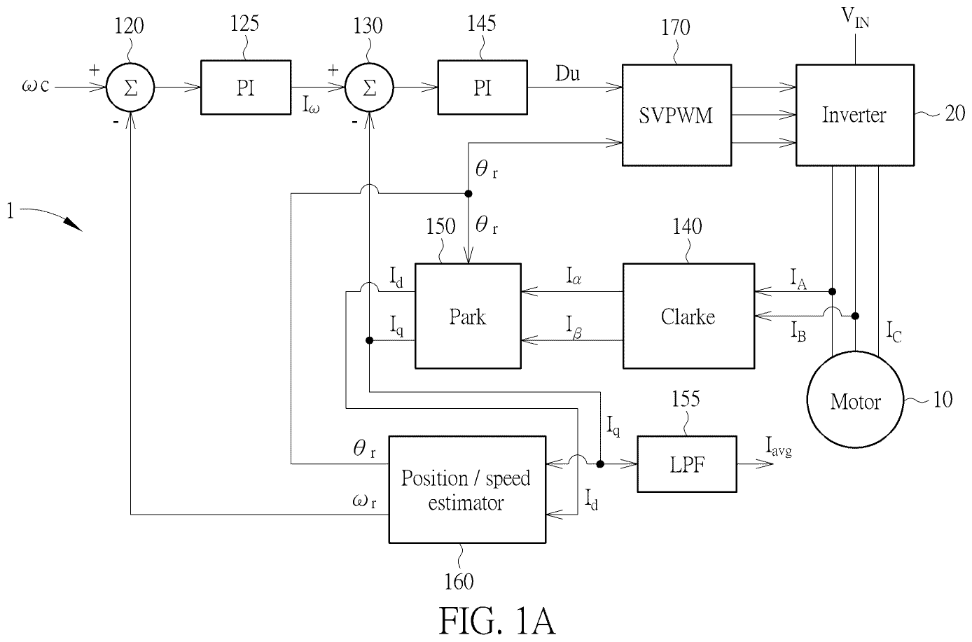

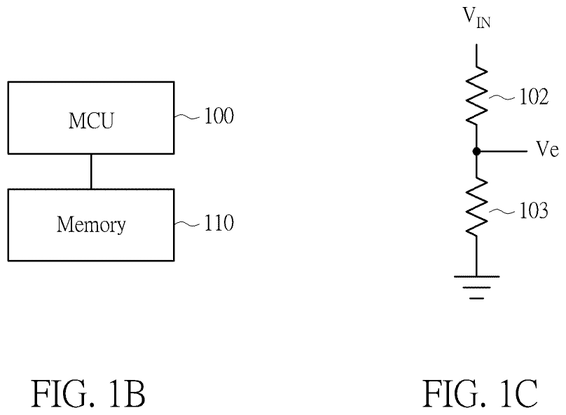

FIGS. 1A, 1B and 1C are diagrams illustrating a motor control system 1 according to an embodiment of the present invention. The motor control system 1 includes a microcontroller (MCU) 100 and a memory 110 (as illustrated in FIG. 1B) coupled together, both of which work together to provide control signals to an inverter 20. The control algorithm employed here is known as field-oriented control (FOC). The microcontroller 100 may generate a control speed ω_{c} (in form of a signal) for the motor 10.

The inverter 20 powers the motor 10 to drive a cooling fan. The inverter 20 generates motor phase currents I_{A}, I_{B}, and I_{C}. The phase currents I_{A} and I_{B} are sampled by a Clarke Transform block 140 for coordinate transformation (i.e., through Clarke transformation). This conversion shifts a three-axis (two-dimensional coordinate system) to a two-axis system, thereby generating stator currents I_{α} and I_{β}.

If the phase currents I_{A}+I_{B}+I_{C}=0, then:

The stator current I_{α} can be expressed as:

$${I}_{α} = {I}_{A}$$

The stator current I_{β} can be expressed as:

$${I}_{β} = \frac{{I}_{A} + ( 2 \times {I}_{B} )}{\sqrt{3}}$$

The stator currents I_{α} and I_{β} are then represented on a two-axis orthogonal system, known as the α-β axis system. These currents are further transformed into another two-axis system that rotates with the rotor flux, accomplished through a Park Transform block 150.

The Park Transform block 150 generates a direct current I_{α} and a quadrature current I_{q} according to the stator currents I_{α} and I_{β} and a rotor angle θᵣ. The currents I_{α} and I_{q} can be described by a two-axis orthogonal rotating coordinate system referred to as the d-q axis. Hence, the currents I_{d} and I_{q} can be generated by the following expressions:

$${I}_{d} = {I}_{α} \times cos ( θ r ) + {I}_{β} \times sin ( θ r )$$

$${I}_{q} = - {I}_{α} \times sin ( θ r ) + {I}_{β} \times cos ( θ r )$$

In the above expressions, the current's field flux component aligns with the direct current I_{d}, while the torque component aligns with the quadrature current I_{q}. The rotor angle can be given by a position and speed estimator 160.

The currents I_{d} and I_{q} can be fed into the position and speed estimator 160. Subsequently, the position and speed estimator 160 can generate a speed signal or (which contains the angular speed) and the rotor angle θᵣ accordingly.

A subtractor 120 performs subtraction with the angular speed and a control speed ω_{c} to generate a first difference and the first difference is input to a Proportional Integral (PI) controller 125. The PI controller 125 then generates a PI signal I_{ω} accordingly. Another subtractor 130 then performs subtraction with the PI signal I_{θ} and the quadrature current I_{q}. Then, a PI controller 145 takes the output of the subtractor 130 to generate a duty signal Du. A space vector pulse width modulation (SVPWM) block 170 then can generate control signals for the inverter 20 according to the duty signal Du and the rotor angle θᵣ.

Consequently, the motor 10 may operate within a feedback loop control, and adjust the average speed of the motor 10 based on the control speed ω_{c}. Additionally, a low-pass filter (LPF) 155 can be employed to generate an average current I_{avg} of the motor 10 by utilizing the quadrature current I_{q}.

In some embodiments, an approach involving generating the average current I_{avg} of the motor 10 based on the input current of inverter 20 may be employed. As illustrated in FIG. 1C, two resistors 102 and 103, constitute a voltage divider for generating a circuit voltage Ve according to the input voltage V_{IN}. The input voltage V_{IN} (which is also related to the input power) may be applied to the motor 10 via the inverter 20. The circuit voltage Ve may be applied to power the microcontroller 100 and/or the memory 110, both of which require less voltage than the motor 10. The memory 110 can be used to store system coefficients, e.g., various system voltages, currents, and thresholds.

The values or signals mentioned above (e.g., θᵣ, I_{d}, I_{q}, I_{avg}, V_{IN}, θᵣ, etc.) may be in forms of voltage, current, analog signal and/or digital signal. The signals may carry appropriate values as specified. Those skilled in the art can readily observe those numerous signals and implement them accordingly.

In certain embodiments, the system coefficient can be derived by the following method: The permanent magnet synchronous motor torque equation can be divided into electrical torque equation (1) and mechanical torque equation (2):

$$T = \frac{3}{2} \cdot \frac{P}{2} \cdot [ ( {L}_{d} - {L}_{q} ) {I}_{d} {I}_{q} + {λ}_{m} {I}_{q} ] \qquad ( 1 )$$

$$T - {T}_{Load} = J α \qquad ( 2 )$$

where:
P is the number of rotor magnet poles (constant)
L_{d} is the d-axis inductance (constant)
L_{q} is the q-axis inductance (constant)
I_{d} is the d-axis current
I_{q} is the q-axis current
λₘ is the permanent magnet flux linkage to the stator (constant)
J is the fan's moment of inertia (constant)
α is angular acceleration
T is the motor driving torque, if considering surface-mounted rotor where L_{d}=L_{q}
then

$$T = \frac{3 P}{4} {λ}_{m} {I}_{q}$$

which can be expressed as T=K_{T}I_{q}
T_{Load} is air resistance+friction resistance, can be expressed as K_{A}ω²+Bω
K_{A} is the wind resistance coefficient (constant)
B is the friction coefficient (constant)
ω is the fan rotation angular speed, if speed is constant then α=0

When considering fan operation at constant speed:

$$T - {T}_{Load} = J α = 0 \qquad ( 3 )$$

$$T = {T}_{Load}$$

Substituting T=K_{T}Iq and T_{Load}=K_{A}ω²+Bω into equation (3):

$${K}_{T} {I}_{q} = {K}_{A} {ω}^{2} + B ω \qquad ( 4 )$$

$${I}_{q} = \frac{{K}_{A}}{{K}_{T}} {ω}^{2} + \frac{B}{{K}_{T}} ω$$

$${I}_{q} = {K}_{1} {ω}^{2} + {K}_{2} ω$$

The system coefficients are K₁ and K₂ in equation (4).

At high speeds where air resistance is much greater than friction resistance, friction resistance can be neglected to obtain:

$${I}_{q} = {K}_{1} {ω}^{2} \qquad ( 5 )$$

The simplified system coefficient is K₁.

In certain embodiments, K₁ and K₂ can be obtained experimentally by measuring the motor's input current and speed during steady-state operation, then performing curve fitting on the collected data.

The circuit configuration of the motor control system 1 can be summarized as follows. The motor control system 1 includes an inverter 20, a motor 10 coupled to the inverter 20, a Clarke Transform block 140 coupled to the inverter 20, a Park Transform block 150 coupled to the Clarke Transform block 140, a position and speed estimator 160 coupled to the Park Transform block 150, a low-pass filter 155 coupled to the position and speed estimator 160, a subtractor 120 coupled to the position and speed estimator 160, a PI controller 125 coupled to the subtractor 120, a subtractor 130 coupled to the PI controller 125 and the Park Transform block 150, and an SVPWM block 170 coupled to the PI controller 145, the position and speed estimator 160, and the inverter 20.

The inverter 20 is powered by the input voltage V_{IN} used to generate phase currents I_{A}, I_{B}, and I_{C} according to an input voltage V_{IN} and control signals. The motor 10 is used to drive a cooling fan according to the phase currents I_{A}, I_{B}, and I_{C}. The Clarke Transform block 140 is used to generate stator currents I_{α} and I_{β} according to the phase currents I_{A}, I_{B}, and I_{C} through Clarke transformation. The Park Transform block 150 is used to generate a direct current I_{d} and a quadrature current I_{q} according to a rotor angle θᵣ, the stator currents I_{α} and I_{β} through Park transformation. The position and speed estimator 160 is used to generate a speed signal or and the rotor angle θᵣ according to the direct current I_{d} and the quadrature current I_{q}. The low-pass filter 155 is used to generate an average current I_{avg} of the motor 10 according to the quadrature current I_{q}. The subtractor 120 is used to generate a first difference signal according a control speed ω_{c} and the speed signal ωᵣ. The PI controller 125 is used to generate a PI signal I_{ω} according to the first difference signal. The subtractor 130 is used to generate a second difference signal according to the PI signal I_{ω} and the quadrature current I_{q}. The PI controller 145 is used to generate a duty signal Du according to the second difference signal. The SVPWM block 170 is used to generate the control signals for the inverter 20 according to the duty signal Du and the rotor angle θᵣ.

The motor control system 1 may further include a microcontroller 100 and a memory 110 coupled to the microcontroller 100. The microcontroller 100 may be used for generating the control speed ω_{c}. The memory 110 may be used to store system coefficients, a current threshold, and/or a maximum power.

In certain embodiments, the motor control system 1 includes a processing and storage subsystem comprising a microcontroller 100 and an associated memory 110 communicatively coupled to the microcontroller 100. This configuration enables real-time control and monitoring of the motor operation while maintaining system parameters and operational thresholds.

The microcontroller 100 serves as the primary processing unit of the motor control system 1 and is configured to execute the motor control algorithm. In particular, the microcontroller 100 generates a control speed signal ω_{c} that defines the desired operational speed of the motor. The microcontroller 100 may adjust this control speed signal ωc in response to various system conditions and operational requirements.

The memory 110 is operatively coupled to the microcontroller 100 and is configured to store multiple categories of operational data. The system coefficients stored in memory relate to specific characteristics of the motor and fan assembly, including motor characteristics, fan design parameters, air-flow resistance factors, and speed-torque relationships. These coefficients are essential for proper system operation and performance optimization.

The memory 110 further stores current threshold values that define acceptable operational boundaries for the system. These encompass normal operating current ranges, maximum allowable current levels, current deviation thresholds for fault detection, and time-based current monitoring parameters. These thresholds enable the system to maintain safe operation and detect potential abnormalities.

Additionally, the memory 110 maintains maximum power parameters that establish power consumption limits for the system. These parameters include maximum input power thresholds, power consumption warning levels, power efficiency targets, and operating range boundaries. These power-related parameters ensure efficient and safe system operation within designed specifications.

In certain embodiments, the current threshold can be determined through the functional relationship between system coefficient K₁ and rotational speed ω. Based on system coefficient K₁, one can calculate the required q-axis current when the fan is rotating at a specific constant speed ω, therefore reasonable upper and lower current thresholds can be calculated through the following equations:

$${I}_{q UpperThreshold} = {K}_{1} ω ( 1 + x \% )$$

$${I}_{q LowerThreshold} = {K}_{1} ω ( 1 - x \% )$$

The allowable variation percentage x % can be set according to practical application requirements, typically ranging between 5% to 20%.

In certain embodiments, the maximum input power threshold can be derived according to the motor input power equation:

$${P}_{e} = \frac{3}{2} Re [ \vec{V} \cdot {\vec{I}}^{*} ] = \frac{3}{2} Re [ ( {V}_{d} + {jV}_{q} ) \cdot ( {I}_{d} - {jI}_{q} ) ] \qquad ( 6 )$$

$${P}_{e} = \frac{3}{2} ( {V}_{d} {I}_{d} + {V}_{q} {I}_{q} )$$

Pe is the input motor power
Rₑ[ ] denotes taking the real part of the operation result within [ ]
V is the motor drive voltage vector
\vec{I}* is the complex conjugate of the motor drive current vector
V_{d} is the d-axis voltage
V_{q} is the q-axis voltage
I_{d} is the d-axis current
I_{q} is the q-axis current

For a surface-mounted permanent magnet synchronous motor (SPM PMSM), when operating without field weakening control, Id is maintained at 0. Thus, equation (6) simplifies to:

$${P}_{e} = \frac{3}{2} {V}_{q} {I}_{q} \qquad ( 7 )$$

The input power can be calculated through equation (7). The maximum input power refers to the maximum input power needed when the motor is running at a constant angular speed. The maximum input power threshold can be calculated based on motor rated parameters and safety margin.

During operation, the microcontroller 100 continuously accesses the memory 110 to perform several critical functions. The microcontroller retrieves stored parameters for comparison with real-time measurements, updates operational data based on current system conditions, references system coefficients for control calculations, and accesses threshold values for fault detection. This continuous interaction between the microcontroller and memory ensures optimal system performance and reliability.

The memory 110 may be implemented using various storage technologies to meet different operational requirements. Non-volatile memory components store permanent parameters that must be retained when power is removed from the system. Random access memory provides high-speed storage for temporary operational data, while flash memory enables storage of updateable system parameters that may need modification during the system's lifetime.

In one embodiment of the present invention, the motor control system 1 comprises a voltage monitoring circuit configured to measure and scale the input voltage supplied to the motor. Specifically, the voltage monitoring circuit includes a first resistor 102 and a second resistor 103 connected in series between an input voltage node and a ground node, thereby forming a voltage divider network. The junction point between the first resistor 102 and the second resistor 103 defines a measurement node for generating a circuit voltage Ve that is proportional to the input voltage V_{IN}.

The voltage divider network operates according to the following relationship:

$$Ve = {V}_{IN} \times R 2 / ( R 1 + R 2 )$$

wherein R1 represents the resistance value of the first resistor 102, and R2 represents the resistance value of the second resistor 103.

In a certain embodiment, the resistance values R1 and R2 can be selected such that the circuit voltage Ve remains within a predetermined range suitable for input to the microcontroller 100 while the input voltage V_{IN} varies within its expected operational range. For example, when the input voltage V_{IN} is at its maximum expected value, the circuit voltage Ve should not exceed the maximum allowable input voltage of the microcontroller 100.

The circuit voltage Ve serves multiple purposes within the motor control system 1. First, it enables real-time monitoring of the input voltage V_{IN}, allowing the system to detect and respond to voltage fluctuations. Second, the measured circuit voltage Ve is utilized by the microcontroller 100 to adjust current measurements and control parameters, thereby maintaining consistent motor operation across varying input voltage conditions.

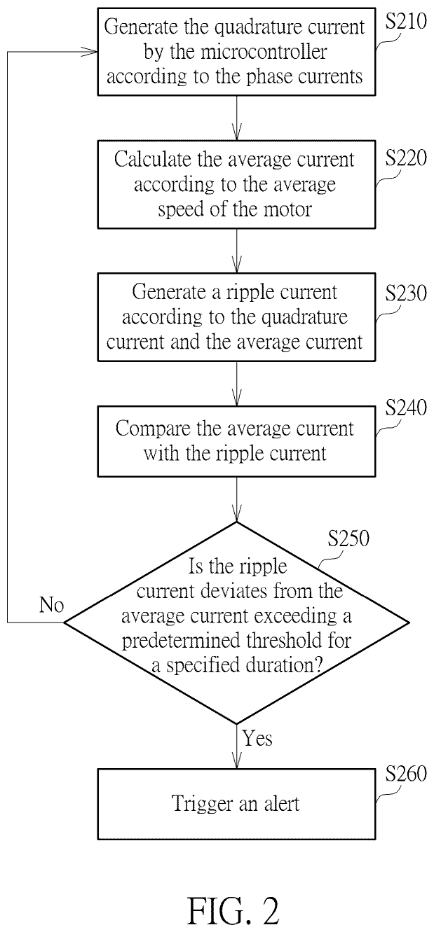

FIG. 2 illustrates a flow diagram presenting a method 200 for predicting failure of a cooling fan implemented by the motor control system 1. The method 200 includes the following steps:
S210: Generate the quadrature current I_{q} by the microcontroller 100 according to the phase currents I_{A}, I_{B}, and I_{C};
S220: Calculate the average current I_{avg} by the LPF 155 according to the average speed of the motor 10;
S230: Generate a ripple current Iᵣₚ by the microcontroller 100 according to the quadrature current I_{q} and the average current I_{avg},
S240: Compare the average current I_{avg} with the ripple current Iᵣₚ;
S250: Determine whether the ripple current Iᵣₚ deviates from the average current I_{avg} exceeding a predetermined threshold for a specified duration; if so, proceed to S270; if not, go back to S210; and
S260: Trigger an alert.

In more details, the process begins (step S210) with the generation of the quadrature current I_{q} by the microcontroller. This involves measuring the phase currents I_{A}, I_{B}, and I_{C} using current sensors, then applying a Clarke Transform to convert the phase currents I_{A}, I_{B}, and I_{C} into stator currents I_{α} and I_{β}. Specifically, I_{α} equals I_{A}, while I_{β} is calculated as I_{β}=I_{A}+(2×I_{B})/\sqrt{3}. The motor control system 1 then applies a Park Transform to generate I_{q}, which is calculated as −I_{α}×sin(θr)+I_{β}×cos(θr), where θᵣ represents the rotor angle.

In step S220, the LPF 155 processes the quadrature current I_{q} to calculate the average current I_{avg}. This creates a baseline signal that represents normal operating conditions and serves as a crucial reference point for detecting any abnormalities in the motor control system 1. The motor control system 1 maintains and updates this baseline during normal operation to account for gradual changes in motor characteristics.

In step S230, the microcontroller 100 then generates a ripple current Iᵣₚ through a series of processing steps. It first subtracts average current I_{avg} from quadrature I_{q} to eliminate low-frequency components, then filters the result through another low-pass filter to remove high-frequency harmonics. This process isolates the mechanical rotation frequency components, resulting in a ripple signal that effectively indicates torque variations in the motor.

In step S240, the comparison process involves retrieving the baseline I_{avg} from memory and comparing it against the newly generated Iᵣₚ. In step S250, the system then evaluates whether the ripple current deviations exceed a predetermined threshold for a specified duration. This time requirement is crucial as it helps prevent false positives that might occur from temporary fluctuations. If the threshold is exceeded consistently over the specified time period, the system moves to generate an alert; if not, it returns to the monitoring phase.

In step S260, when sustained deviation is detected, the system generates an alert signal that can be transmitted to a remote monitoring system via a communication interface. This alert indicates a potential ball bearing (of the motor 10) abnormality that requires attention. The entire process represents a non-invasive approach to monitoring bearing health, offering a significant advantage over traditional vibration analysis methods by enabling early detection of potential failures without requiring direct physical access to the bearings.

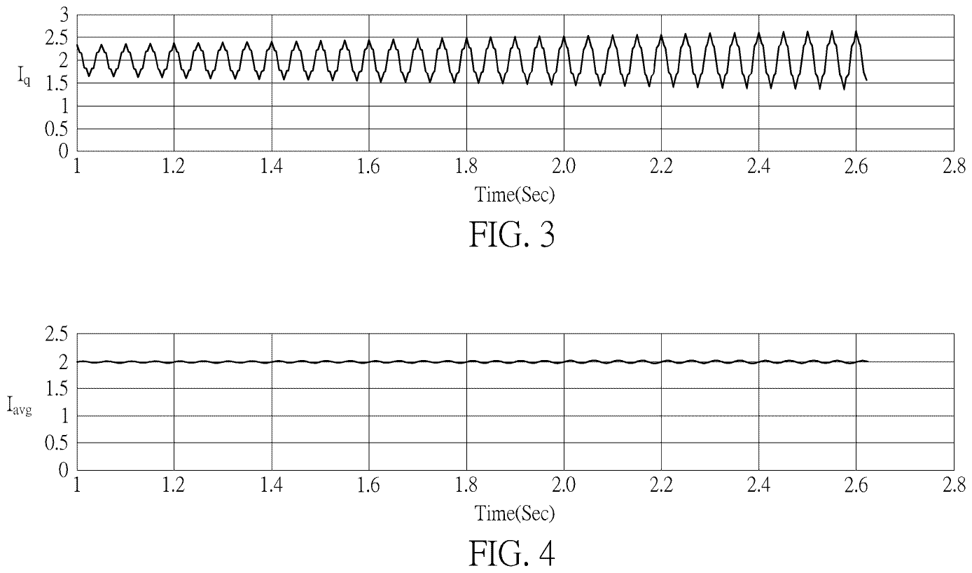

FIG. 3 illustrates an exemplary quadrature current I_{q} generated by the microcontroller 100 during the operation of motor 10. The quadrature current I_{q} represents the torque-producing component of the motor current, obtained through coordinate transformation of the measured phase currents. The signal exhibits characteristic variations that correspond to the dynamic behavior of the motor during operation.

As depicted in FIG. 3, the quadrature current I_{q} manifests as a time-varying waveform with distinct amplitude modulations. These modulations arise from the electromagnetic interactions between the stator and rotor, as well as mechanical factors including, but not limited to, the ball bearing conditions. The signal pattern of the quadrature current I_{q} shown incorporates both low-frequency components related to the average operation of motor 10 and higher-frequency components that may indicate mechanical anomalies.

The quadrature current I_{q} serves as the primary input for the bearing abnormality detection process. When processed through the low-pass filter (LPF) 155, this signal yields the average current I_{avg} that establishes the baseline for normal operating conditions. The temporal characteristics of the quadrature current, including its amplitude variations and frequency components, provide crucial information about the mechanical state of the motor's ball bearings.

In certain embodiments, the microcontroller 100 continuously samples and processes this quadrature current I_{q} at a predetermined sampling rate sufficient to capture relevant mechanical frequency components. The signal processing maintains phase coherency and amplitude fidelity necessary for accurate bearing condition assessment. The quadrature current's characteristics may vary according to motor specifications, operating conditions, and bearing configurations, necessitating adaptive processing techniques for optimal abnormality detection.

FIG. 4 illustrates an exemplary average current I_{avg} (as baseline signal) generated from the quadrature current I_{q} by the LPF 155 according to an embodiment of the present invention. The average current I_{avg} represents the averaged motor current characteristics under normal operating conditions, serving as a reference point for detecting bearing abnormalities. This signal is obtained through the application of a low-pass filtering operation on the quadrature current I_{q}, effectively removing high-frequency components while preserving the fundamental operational characteristics of the motor.

The average current I_{avg}, as depicted in FIG. 4, manifests as a smoothed waveform that captures the essential low-frequency components of the motor's current consumption. Its characteristics reflect the steady-state operation of the motor, incorporating factors such as the nominal load conditions, basic mechanical resistance, and standard operating parameters. The relatively stable nature of this signal provides a reliable reference against which deviations in motor behavior can be detected.

In certain embodiments, the average current I_{avg} is continuously updated and stored in the memory 110, allowing for adaptive compensation of gradual changes in motor characteristics over time. This dynamic updating mechanism ensures that the detection system remains sensitive to acute abnormalities while accommodating normal wear and environmental variations. The temporal evolution of the average current I_{avg} may exhibit gradual modifications reflecting the natural aging of the motor components, while maintaining sufficient stability to serve as a reference for abnormality detection.

The low-pass filter 155 can be specifically designed to extract the average current I_{avg} while maintaining sufficient temporal resolution for effective comparison with the instantaneous motor current characteristics. The filtering operation can be optimized to preserve information relevant to bearing condition assessment while suppressing noise and transient variations that could otherwise lead to false detections.

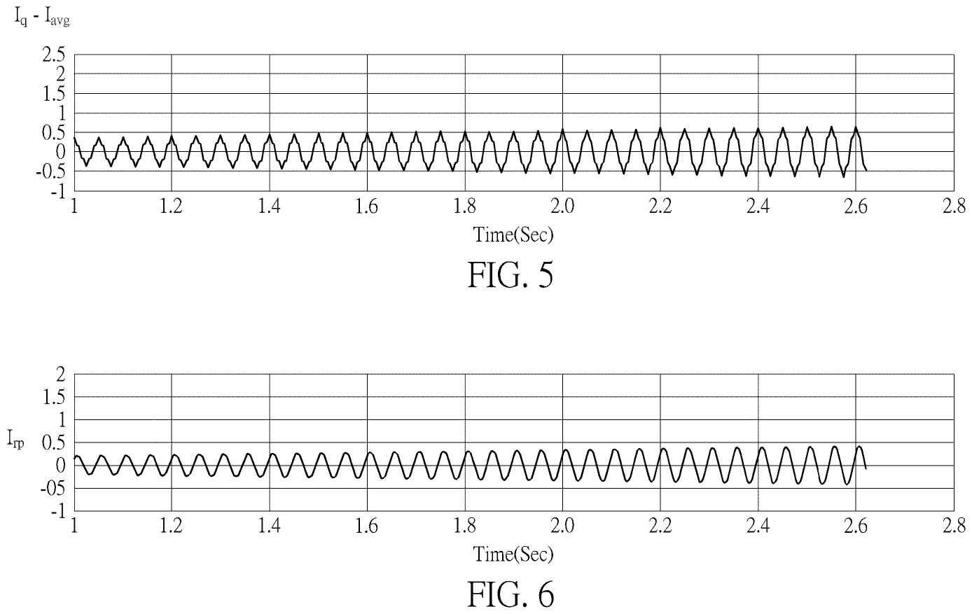

FIG. 5 illustrates the resultant signal obtained from the subtraction operation between the quadrature current I_{q} and the average current I_{avg} according to an embodiment. This subtraction operation represents a critical signal processing step in the detection methodology, wherein the low-frequency components associated with normal motor operation are effectively removed from the quadrature current.

The illustrated signal, as depicted in FIG. 5, demonstrates the outcome of subtracting the average current I_{avg} from the quadrature current I_{q}, thereby isolating variations that deviate from the established normal operating conditions. This intermediate signal retains both mechanical frequency components and higher-frequency harmonics that may be indicative of bearing abnormalities. The subtraction operation effectively eliminates the steady-state component of the motor current, allowing for enhanced visibility of potential bearing-related anomalies.

In certain embodiments, this subtraction process is performed in real-time by the microcontroller 100, maintaining precise temporal alignment between the quadrature current and the average current to ensure accurate anomaly detection. The resulting signal preserves the dynamic characteristics of motor operation while emphasizing deviations from normal behavior. This intermediate signal serves as input to subsequent filtering operations that further refine the detection of bearing-specific abnormalities.

The amplitude and temporal characteristics of this differential signal provide valuable information about instantaneous deviations from normal motor operation. These deviations, when properly filtered and analyzed, can serve as early indicators of developing bearing problems, allowing for timely intervention before catastrophic failure occurs. The signal processing parameters are specifically optimized to maintain sensitivity to bearing-related anomalies while minimizing the influence of normal operational variations.

FIG. 6 illustrates the ripple current Iᵣₚ obtained through subsequent filtering of the differential signal from the previous operation according to an embodiment of the present invention. This ripple current Iᵣₚ is generated when the microcontroller 100 applies a low-pass filter 155 to the result of the I_{q}−I_{avg} subtraction, effectively isolating the mechanical rotation frequency components that are particularly relevant to bearing condition assessment.

The ripple current Iᵣₚ, as depicted in FIG. 6, represents the final processed signal used for bearing abnormality detection. After the removal of the average current component through subtraction, this additional filtering operation eliminates high-frequency harmonic components while preserving the frequency range associated with mechanical anomalies. The resulting waveform exhibits characteristics that directly correlate with potential bearing irregularities, providing a clear indicator for the detection system.

In certain embodiments, the low-pass filtering parameters are specifically optimized to isolate the frequency components most relevant to bearing condition monitoring. This filtered ripple current Iᵣₚ serves as the primary metric for comparison against predetermined thresholds, enabling the motor control system 1 to identify potential bearing abnormalities when the amplitude of the ripple current Iᵣₚ exceeds these thresholds for a specified duration. The temporal characteristics of the ripple current Iᵣₚ can be maintained with sufficient fidelity to ensure reliable detection of developing bearing problems.

The amplitude variations in the ripple current Iᵣₚ provide crucial information about the mechanical state of the ball bearings of the motor 10. When these variations exceed predetermined thresholds over specified time periods, they trigger the system's alert mechanism, indicating potential bearing abnormalities that require attention. This filtered signal forms the basis for the system's non-invasive approach to bearing condition monitoring, offering advantages over traditional vibration-based analysis methods by enabling early detection without requiring direct physical access to the bearings.

It should be noted that in field-oriented control (FOC) of BLDC motors, the quadrature current I_{q} represents the torque-producing component of the motor current. The quadrature current I_{q} have a direct physical relationship to the mechanical aspects of the motor's operation. Specifically, quadrature current I_{q} is perpendicular (90 degrees, hence “quadrature”) to the rotor's magnetic field, making it the component that generates the electromagnetic torque causing rotor rotation. This characteristic makes the quadrature current I_{q} particularly valuable for bearing detection because it directly corresponds to the torque output of the motor, where any mechanical resistance or friction in the bearings requires additional torque to overcome, manifesting as variations in the quadrature current I_{q}. As bearings begin to wear or develop abnormalities, they create periodic variations in the mechanical load, which appear as ripples or patterns in the quadrature current I_{q}, with the frequency and amplitude of these ripples potentially indicating specific types of bearing problems. The quadrature current I_{q} captures the motor's dynamic response to mechanical loads, where normal bearing operation produces a characteristic baseline pattern, and deviations from this pattern can indicate developing bearing problems, responding in real-time to changes in mechanical conditions. This fundamental physical relationship between bearing condition and quadrature current makes quadrature current I_{q} an ideal parameter for non-invasive bearing monitoring, as described in the invention, which leverages this relationship by analyzing the patterns and variations in quadrature current I_{q} to detect early signs of bearing wear or damage before they lead to catastrophic failure.

The various embodiments described above have disclosed a system and methods for predicting failure of the cooling fan. Thus, the failures in early stage can be quickly detected and be addressed promptly.

The various embodiments described above presents a significant advancement in the field of motor maintenance and monitoring, specifically focusing on ball bearing abnormality detection. This innovative approach offers a non-invasive monitoring solution that eliminates the need for direct physical access to bearings, utilizing existing current sensing infrastructure within the motor control system. By leveraging sophisticated signal processing techniques and current ripple analysis, the system can detect potential bearing problems without requiring system disassembly or additional sensor installation.

One of the most significant advantages of this invention lies in its early detection capabilities. The system continuously monitors current ripple patterns during motor operation, enabling the identification of subtle changes in bearing conditions before they develop into catastrophic failures. This early warning capability is achieved through advanced signal processing techniques that effectively isolate relevant frequency components while eliminating interference from normal operational variations. The system's adaptive nature allows it to account for gradual changes in motor characteristics over time while maintaining sensitivity to acute abnormalities.

From a cost perspective, the invention provides a highly efficient solution by utilizing existing motor control hardware rather than requiring expensive vibration analysis equipment. This approach significantly reduces implementation costs while delivering comparable or superior monitoring capabilities. The system's ability to enable condition-based maintenance scheduling helps optimize maintenance operations, reducing unnecessary preventive maintenance activities while preventing unexpected failures and emergency repairs. This proactive approach extends equipment life through timely intervention and minimizes both maintenance costs and system downtime.

The practical implementation of this technology offers substantial operational benefits across various applications. The system provides continuous health monitoring without interrupting normal operations, enabling remote monitoring capabilities that enhance maintenance efficiency. Its compatibility with existing BLDC motor control systems and scalability across different motor sizes and types make it particularly valuable in diverse applications, including cooling fans, pumps, and HVAC systems. The technology's adaptability to different operating environments further extends its utility across various industrial and commercial settings.

This invention represents a transformative approach to motor maintenance technology, offering a practical, cost-effective solution that overcomes the limitations of traditional vibration analysis methods. By enabling predictive maintenance through non-invasive monitoring, the system helps optimize operational efficiency, reduce maintenance costs, and extend equipment life across a wide range of applications. The combination of sophisticated signal processing, early detection capabilities, and practical implementation makes this invention a significant contribution to the field of motor maintenance and reliability engineering.

The terms “coupled,” “connected”, “connecting,” “electrically connected,” etc., are used interchangeably herein to generally refer to the condition of being electrically connected (through wire or wireless means). Similarly, a first entity is considered to be in “communication” or “connection” with a second entity (or entities) when the first entity electrically sends and/or receives (through wire or wireless means) information signals to/from the second entity regardless of the type (analog or digital) of those signals. It is further noted that various figures (including component diagrams) shown and discussed herein are for illustrative purpose only, and are not drawn to scale.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The various illustrative components, logic, logical blocks, modules, circuits, operations and algorithm processes described in connection with the implementations disclosed herein may be implemented as electronic hardware, firmware, software, or combinations of hardware, firmware or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

The hardware and data processing apparatus used to implement the various illustrative components, logics, logical blocks, modules and circuits described in connection with the aspects disclosed herein may be implemented or performed with a general purpose single-chip processor or multi-chip processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, for example, a combination of a DSP and a microprocessor, multiple microprocessors, one or more microprocessors in conjunction with a DSP core, or any other such configuration. In some implementations, particular processes, operations and methods may be performed by circuitry that is specific to a given function.

As described above, in some aspects implementations of the subject matter described in this specification can be implemented as software. For example, various functions of components disclosed herein or various blocks or steps of a method, operation, process or algorithm disclosed herein can be implemented as one or more modules of one or more computer programs. Such computer programs can include non-transitory processor-executable or computer-executable instructions encoded on one or more tangible processor-readable or computer-readable storage media for execution by, or to control the operation of, data processing apparatus including the components of the devices described herein. By way of example, and not limitation, such storage media may include RAM, ROM, EEPROM, CD-ROM or other optical disk storage, magnetic disk storage or other magnetic storage devices, or any other medium that may be used to store program code in the form of instructions or data structures. Combinations of the above should also be included within the scope of storage media.

Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for detecting abnormalities of a motor, the method comprising:
generating, by a microcontroller, a quadrature current;
calculating, using a low-pass filter, an average current based on the quadrature current;
generating, by the microcontroller, a ripple current;
comparing the ripple current with the average current;
determining whether the ripple current deviates from the average current by more than a predetermined threshold for a specified duration; and
triggering an alert signal when the ripple current deviates from the average current by more than the predetermined threshold for the specified duration.

2. The method of claim 1, wherein generating the quadrature current comprises:
measuring phase currents of the motor;
converting the phase currents to a two-phase current using a Clarke transform; and
converting the two-phase current to the quadrature current using a Park transform.

3. The method of claim 2, wherein the Park transform generates the quadrature current based on a rotor angle.

4. The method of claim 1, wherein generating the ripple current comprises:
subtracting the average current from the quadrature current to remove low-frequency components to obtain an intermediate current; and
filtering the intermediate current to remove high-frequency components.

5. The method of claim 1, wherein the average current is updated over time during normal operation of the motor.

6. The method of claim 1, further comprising transmitting the alert signal to a remote monitoring system via a communication interface.

7. The method of claim 1, wherein the motor comprises a brushless DC (BLDC) motor controlled by a field-oriented control (FOC) algorithm.

8. The method of claim 1, wherein calculating the average current comprises filtering the quadrature current through the low-pass filter to remove high-frequency components.

9. The method of claim 1, wherein determining whether the ripple current deviates from the average current comprises monitoring amplitude changes in the ripple current.

10. The method of claim 1, wherein the motor operates within a feedback loop control for adjusting motor speed based on a speed control signal.

11. A motor control system comprising:
an inverter configured to generate a first phase current, a second phase current, and a third phase current according to an input voltage and control signals;
a motor coupled to the inverter, configured to drive a cooling fan according to the first phase current, the second phase current, and the third phase current;
a Clarke Transform block coupled to the inverter, configured to generate a first stator current and a second stator current according to the first phase current and the second phase current through Clarke transformation;
a Park Transform block coupled to the Clarke Transform block, configured to generate a direct current and a quadrature current according to a rotor angle, the first stator current and the second stator current through Park transformation;
a position and speed estimator coupled to the Park Transform block, configured to generate a speed signal and the rotor angle according to the direct current and the quadrature current;
a low-pass filter coupled to the position and speed estimator, configured to generate an average current of the motor according to the quadrature current;
a first subtractor coupled to the position and speed estimator, configured to generate a first difference signal according to a control speed and the speed signal;
a first Proportional Integral (PI) controller coupled to the first subtractor, configured to generate a PI signal according to the first difference signal;
a second subtractor coupled to the first PI controller and the Park Transform block, configured to generate a second difference signal according to the PI signal and the quadrature current;
a second Proportional Integral (PI) controller coupled to the second subtractor, configured to generate a duty signal according to the second difference signal;
a space vector pulse width modulation (SVPWM) block coupled to the second PI controller, the position and speed estimator, and the inverter, configured to generate the control signals for the inverter according to the duty signal and the rotor angle;
wherein:
the low-pass filter generates a ripple current according to the average current and the quadrature current; and
an alert signal is generated when the ripple current exceed a predetermined deviation threshold.

12. The motor control system of claim 11 further comprising:
a microcontroller configured to generate the control speed; and
a memory coupled to the microcontroller, configured to store system coefficients, the predetermined deviation threshold, and/or a maximum power.

13. The motor control system of claim 11 further comprising:
a first resistor and a second resistor coupled in series to form a voltage divider, wherein the voltage divider generates a circuit voltage according to the input voltage.

14. The motor control system of claim 11, wherein the motor comprises a brushless DC (BLDC) motor.

15. The motor control system of claim 1, wherein the speed signal and average current are averaged over a predetermined time period while the control speed remains constant.
